(19) United States
(12) Patent Application Publication
(10) Pub. No.: US 2016/0336269 A1
(43) Pub. Date: Nov. 17, 2016

(54) SEMICONDUCTOR STRUCTURE AND PROCESS THEREOF

(71) Applicant: UNITED MICROELECTRONICS CORP., Hsin-Chu City (TW)

(72) Inventors: Kun-Ju Li, Tainan City (TW); Shu Min Huang, Tainan City (TW); Kuo-Chin Hung, Changhua County (TW); Po-Cheng Huang, Kaohsiung City (TW); Yu-Ting Li, Chiayi City (TW); Pei-Yu Lee, Taichung City (TW); Min-Chuan Tsai, New Taipei City (TW); Chih-Hsun Lin, Ping-Tung County (TW); Wu-Sian Sie, Tainan City (TW); Jen-Chieh Lin, Kaohsiung City (TW)

(21) Appl. No.: 14/709,500

(22) Filed: May 12, 2015

(51) Int. Cl. H01L 23/535; H01L 21/768; H01L 23/532

(52) U.S. Cl. CPC H01L 23/535; H01L 23/53266; H01L 21/76843; H01L 21/7684; H01L 21/76895

(57) ABSTRACT

A semiconductor process includes the following steps. A dielectric layer having a recess is formed on a substrate. A barrier layer is formed to cover the recess, thereby the barrier layer having two sidewall parts. A conductive layer is formed on the barrier layer by an atomic layer deposition process, thereby the conductive layer having two sidewall parts. The two sidewall parts of the conductive layer are pulled down. A conductive material fills the recess and has a part contacting the two sidewall parts of the barrier layer protruding from the two sidewall parts of the conductive layer, wherein the equilibrium potential difference between the barrier layer and the conductive layer is different from the equilibrium potential difference between the barrier layer and the conductive material. Moreover, the present invention also provides a semiconductor structure formed by said semiconductor process.

### BACKGROUND OF THE INVENTION

1. Field of the Invention

The present invention relates generally to a semiconductor structure and process thereof, and more specifically to a semiconductor structure including plugs and process thereof.

2. Description of the Prior Art

Field effect transistors are important electronic devices in the fabrication of integrated circuits, and as the size of the semiconductor device becomes smaller and smaller, the fabrication of the transistors also improves and is constantly enhanced for fabricating transistors with smaller sizes and higher quality. In the conventional method of fabricating transistors, agate structure is first formed on a substrate, and a lightly doped drain (LDD) is formed on the two corresponding sides of the gate structure. Next, a spacer is formed on the sidewall of the gate structure and an ion implantation process is performed to forma source/drain region within the substrate by utilizing the gate structure and spacer as a mask. In order to incorporate the gate, source, and drain into the circuit, contact plugs are utilized for interconnection purposes. Each of the contact plugs include a barrier layer surrounding a low resistivity material to prevent the low resistivity material from diffusing outward to other areas. As the miniaturization of semiconductor devices increases, filling the barrier layer and the low resistivity into a contact hole has become an important issue to form the contact plug and maintaining or enhancing the performances of formed semiconductor devices as well.

### SUMMARY OF THE INVENTION

The present invention relates generally to a semiconductor structure and process thereof, which forms and pulls down a conductive layer between a barrier layer and a conductive material to increase gap filling and reduce galvanic corrosion.

The present invention provides a semiconductor process including the following steps. A dielectric layer having a recess is formed on a substrate . A barrier layer is formed to cover the recess . A conductive layer is formed on the barrier layer by an atomic layer deposition process, thereby the conductive layer having two sidewall parts. The two sidewall parts of the conductive layer are pulled down.

The present invention provides a semiconductor structure including a dielectric layer, a barrier layer, a conductive layer and a conductive material. The dielectric layer having a recess is located on a substrate. The barrier layer conformally covers the recess, thereby the barrier layer having two sidewall parts. The conductive layer conformally covers the barrier layer, wherein the conductive layer has two sidewall parts, and the two sidewall parts of the barrier layer protrude from the two sidewall parts of the conductive layer. The conductive material fills the recess and has a part contacting the two sidewall parts of the barrier layer protruding from the two sidewall parts of the conductive layer, wherein the equilibrium potential difference between the barrier layer and the conductive layer is different from the equilibrium potential difference between the barrier layer and the conductive material.

According to the above, the present invention provides a semiconductor structure and process thereof, which forms a dielectric layer having a recess on a substrate, forms a barrier layer to cover the recess, forms a conductive layer on the barrier layer by an atomic layer deposition (ALD) process, and then pulls down sidewall parts of the conductive layer, thereby the conductive layer can be entirely covered by a conductive material filling the recess. As a result, the conductive layer can avoid being damaged or polished by processes such as a planarization process later performed on the conductive material and the barrier layer for forming a plug. Therefore, the galvanic corrosion between the barrier layer and the conductive layer can be avoided by selecting the forming process of the conductive material, which can make the equilibrium potential difference between the barrier layer and the conductive layer be different from the equilibrium potential difference between the barrier layer and the conductive material.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 schematically depict cross-sectional views of a semiconductor process according to an embodiment of the present invention.

FIG. 7 schematically depicts a cross-sectional view of a semiconductor structure according to an embodiment of the present invention.

FIG. 8 schematically depicts a cross-sectional view of a semiconductor structure according to another embodiment of the present invention.

FIG. 9 schematically depicts a cross-sectional view of a semiconductor structure according to another embodiment of the present invention.

### DETAILED DESCRIPTION

FIGS. 1-6 schematically depict cross-sectional views of a semiconductor process according to an embodiment of the present invention. As shown in FIG. 1, a substrate 110 is provided. The substrate 110 may be a semiconductor substrate such as a silicon substrate, a silicon containing substrate, a III-V group-on-silicon (such as GaN-on-silicon) substrate, a graphene-on-silicon substrate or a silicon-on-insulator (SOI) substrate. A dielectric layer 120 having a recess R is formed on the substrate 110. More precisely, a dielectric material (not shown) may blanketly cover the substrate 110; the dielectric material is planarized to form the dielectric layer 120 having a flat top surface S1; and then, the dielectric layer 120 is etched by a dry etching process or/and a wet etching process to form the recess R in the dielectric layer 120 and expose the substrate 110, but it is not restricted thereto. The dielectric layer 120 may be an inter-level dielectric layer, which may be an oxide layer, but it is not limited thereto.

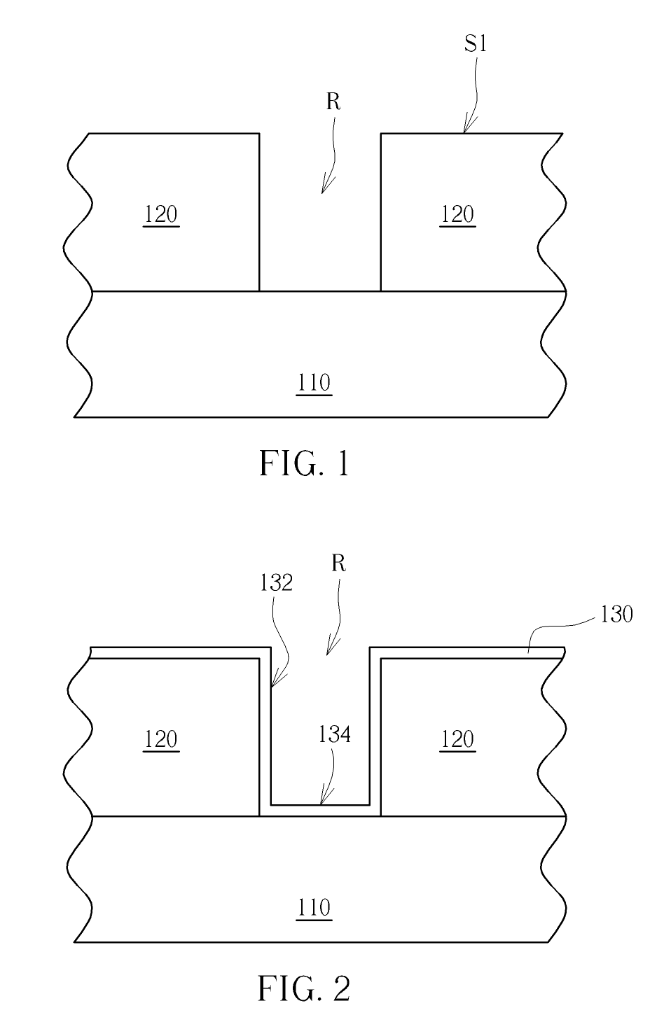

As shown in FIG. 2, a barrier layer 130 is formed to conformally cover the recess R and the dielectric layer 120. Thereby, the barrier layer 130 has two sidewall parts 132 and a bottom part 134 in the recess R. The barrier layer 130 may be a titanium nitride layer, but it is not limited thereto. In one case, the barrier layer 130 may be formed by a chemical vapor deposition (CVD) process, but it is not limited restricted thereto. In another embodiment, the barrier layer 130 may be formed by an atomic layer deposition (ALD) process to have better step coverage.

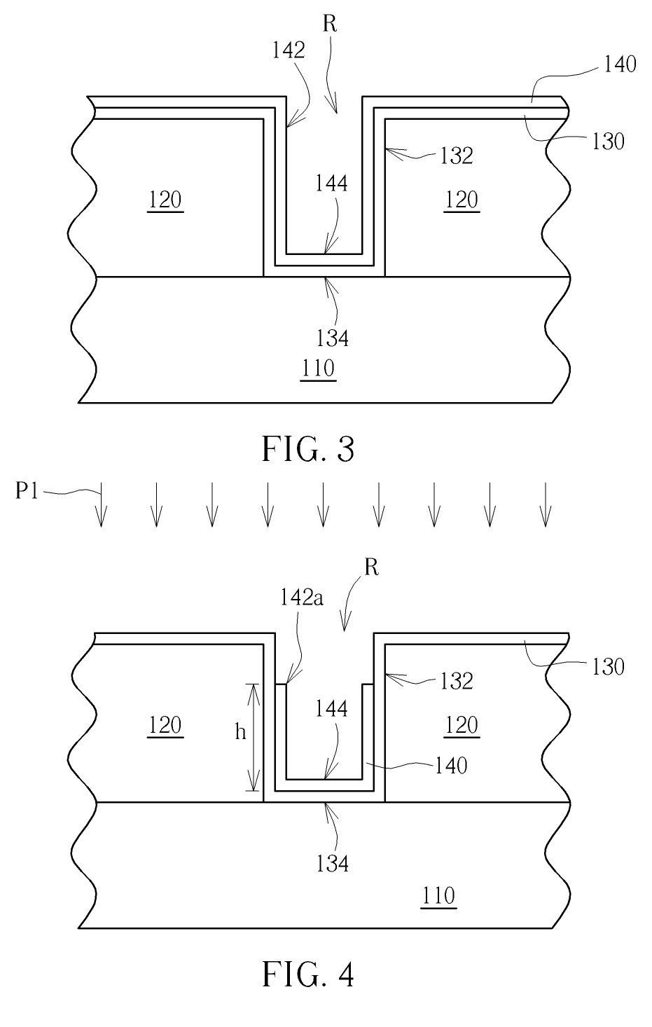

As shown in FIG. 3, a conductive layer 140 is formed to conformally cover the barrier layer 130. In the present invention, the conductive layer 140 is formed by an atomic layer deposition process to have better step coverage and serve as a seeding layer. Therefore, the conductive layer 140 also has two sidewall parts 142 and one bottom part 144 corresponding to the two sidewall parts 132 and the bottom part 134 of the barrier layer 130. In this embodiment, the conductive layer 140 is composed of tungsten, but it is not limited thereto. In another embodiment, the conductive layer 140 may be composed of copper or others.

Thereafter, the two sidewall parts 142 of the conductive layer 140 are pulled down, thereby two sidewall parts 142a of the conductive layer 140 being formed, as shown in FIG. 4. The two sidewall parts 132 of the barrier layer 130 thus protrude from the two sidewall parts 142a of the conductive layer 140. In this embodiment, the two sidewall parts 142 of the conductive layer 140 are pulled down by a dry etching process P1, which etches the two sidewall parts 142 without etching the bottom part 144, but it is not limited thereto. In a preferred embodiment, the dry etching process P1 may be a fluorine containing dry etching process such as a dry etching process containing nitrogen trifluoride (NF₃) . The height h of the two sidewall parts 142a thus can be controlled by adjusting the etching flow rate and the etching time of the dry etching process P1. The height h of the two sidewall parts 142a is preferably 85%-95% of an original height of the two sidewall parts 142. In a preferred embodiment, the conductive layer 140 is formed and pulled down in-situ for preventing pollution. That is, the conductive layer 140 is formed and pulled down without exposing to the air, which may be carried out in one same chamber, or one same tool with different cluster chambers.

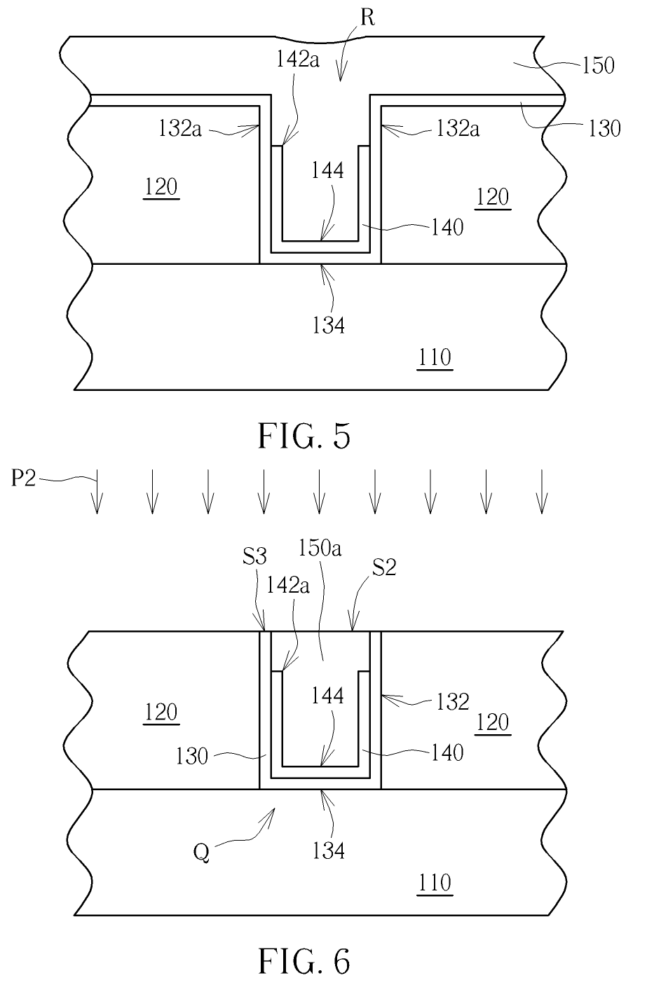

As shown in FIG. 5, a conductive material 150 fills the recess R. The conductive material 150 thus contacts exposed parts 132a of the barrier layer 130, and has a T-shaped cross-sectional profile. In this embodiment, the conductive material 150 is composed of tungsten, which is formed by a chemical vapor deposition (CVD) process, but it is not limited thereto. Since the conductive layer 140 and the conductive material 150 are both composed of tungsten, and the conductive material 150 is formed by a chemical vapor deposition (CVD) process and the conductive layer 140 is formed by an atomic layer deposition (ALD) process, the equilibrium potential difference between the barrier layer 130 and the conductive layer 140 is different from the equilibrium potential difference between the barrier layer 130 and the conductive material 150, leading to difference of polishing rates or etching rate in later processes. In a preferred case, the conductive layer 140 and the conductive material 150 are formed in-situ. That is, the conductive layer 140 is formed and pulled down, and the conductive material 150 is formed in-situ but with different forming processes. In this embodiment, the conductive layer 140 and the conductive material 150 are both composed of tungsten but with different forming processes, thereby the equilibrium potential difference between the barrier layer 130 and the conductive layer 140 is different from the equilibrium potential difference between the barrier layer 130 and the conductive material 150. In other embodiments, the conductive layer 140 and the conductive material 150 may be both composed of copper formed by dual damascene processes, depending upon practical requirements.

Thereafter, a planarization process P2 is performed on the conductive material 150 and the barrier layer 130 until the dielectric layer 120 is exposed, thereby the sidewall parts 132 of the barrier layer 130 and a conductive material 150a are remaining, as shown in FIG. 6, wherein the conductive material 150a has a top surface S2 level with top surfaces S3 of the two sidewall parts 132. In this embodiment, the planarization process P2 may be a chemical mechanical polishing (CMP) process, and the slurry of the planarization process P2 may include hydrogen peroxide (H2O2), but it is not limited thereto.

According to the above figures, since the equilibrium potential difference between the barrier layer 130 and the conductive layer 140 is different from the equilibrium potential difference between the barrier layer 130 and the conductive material 150, the planarizing rate of the planarization process P2 to the conductive material 150 is different from the planarizing rate of the planarization process P2 to the conductive layer 140. Due to the conductive layer 140 being pulled down to have the sidewall parts 142a covered by the conductive material 150 in the recess R, the sidewall parts 142a will not be polished by the planarization process P2. Thereby, the galvanic corrosion between the barrier layer 130 and the conductive layer 140 can be avoided. The galvanic corrosion is an electrochemical process in which one metal corrodes preferentially to another when both metals are in electrical contact, in the presence of an electrolyte. More precisely, metals and metal alloys all possess different electrode potentials—a relative measure of a metal's tendency to become active in a given electrolyte. The more active, or less noble, a metal is the more likely it will form an anode in an electrolytic environment. While the more noble a metal is, the more likely it will form a cathode when in the same environment . The electrolyte acts as a conduit for ion migration, moving metal ions from the anode to the cathode. The anode metal, as a result, corrodes more quickly than it otherwise would, while the cathode metal corrodes more slowly and, in some cases, may not corrode at all, hence causing the anode metal such as tungsten loss.

For example, in the slurry of the planarization process P2, the equilibrium potential of the barrier layer 130 (Titanium nitride) is V1 (−0.2 volts), the equilibrium potential of the conductive layer 140 (ALD tungsten) is V2 (−0.6 volts), and the equilibrium potential of the conductive material 150 (CVD tungsten) is V3 (−0.4 volts). The potential difference between V1 and V2 is 0.4 volts (V1−V2=−0.2v−(−0.6v)=0.4v) and the potential difference between V1 and V3 is 0.2 volts (V1−V3=−0.2v−(−0.4v)=0.2v). The potential difference of 0.4 volts will result in worse galvanic corrosion than the potential difference of 0.2 volts. Due to the conductive layer 140 being pulled down in the present invention, the worse galvanic corrosion can be avoided.

Above all, the present invention provides a conductive layer 140, which is pulled down to prevent the conductive layer 140 from being planarized by the planarization process P2 as well as improving the conductive material 150 filling, thereby a structure Q of the present invention as shown in FIG. 6 can be formed. The structure Q of FIG. 6 can be applied in many processing steps of a semiconductor process such as a contact plug forming process step, a via plug forming process step, a metal gate forming process step, a damascene process, or others. Besides, the structure Q of FIG. 6 can be formed on a substrate having conductive layers thereon, a source/drain, a metal silicide on a source/drain, a gate, a metal line, or others.

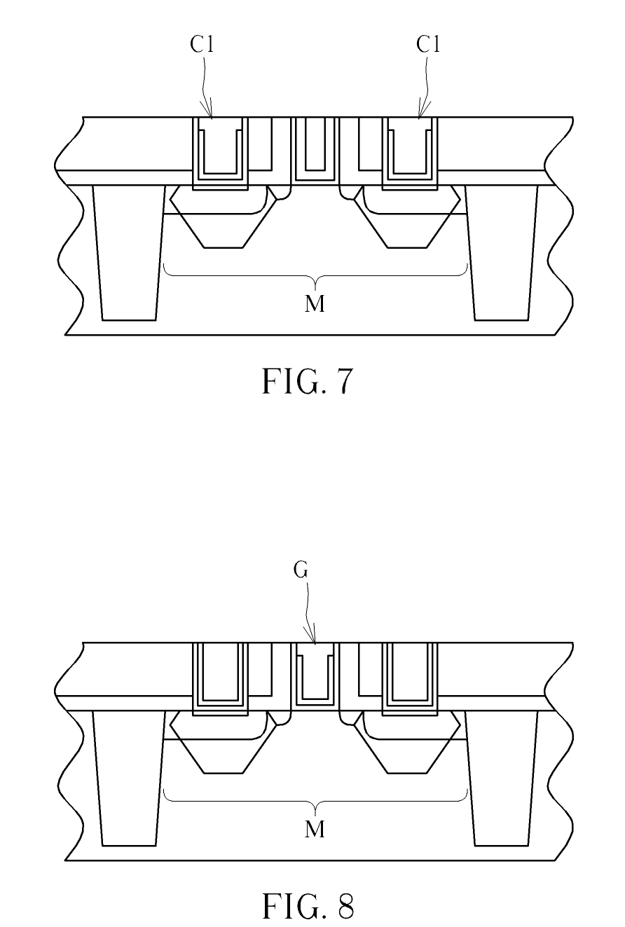

As shown in FIG. 7, the present invention is applied in a contact plug forming process step. That is, contact plugs C1 of a MOS transistor M have the structure Q of FIG. 6.

As shown in FIG. 8, the present invention is applied in a metal gate forming process step. That is, a metal gate G of a MOS transistor M may include the structure Q of FIG. 6. The metal gate G must include other layers such as a dielectric layer, a work function layer, etc., for clarifying the present invention, and these layers are not depicted. The sidewall parts 142a of the structure Q may include sidewall parts of a barrier layer, a work function layer or other layers.

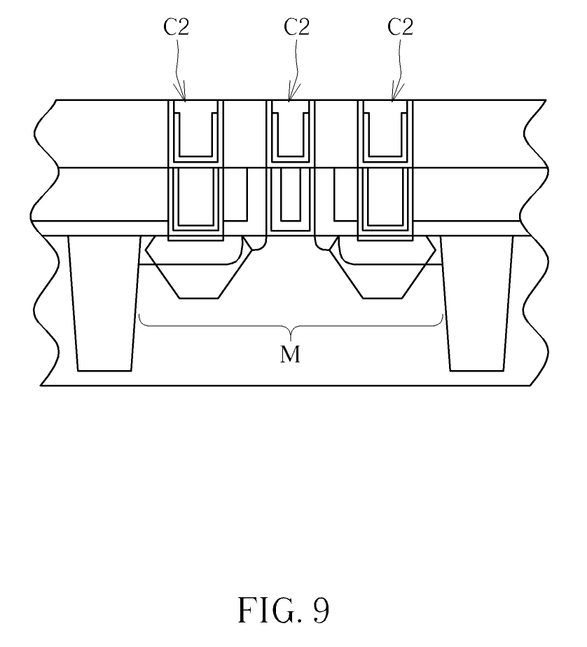

As shown in FIG. 9, the present invention is applied in a via plug forming process step. That is, contact plugs C2 directly contacting a MOS transistor M have the structure Q of FIG. 6.

To summarize, the present invention provides a semiconductor structure and process thereof, which forms a barrier layer covering a recess in a dielectric layer, forms a conductive layer on the barrier layer by an atomic layer deposition (ALD) process for serving as a seeding layer, pulls down sidewall parts of the conductive layer, and then fills a conductive material by a chemical vapor deposition (CVD) process in the recess and entirely covering the conductive layer. Thereafter, a planarization process is performed on the conductive material and the barrier layer to form a plug, which may be a contact plug, a via plug, a metal gate or others.

Thereby, the equilibrium potential difference between the barrier layer and the conductive layer is different from the equilibrium potential difference between the barrier layer and the conductive material due to the different forming processes of the conductive layer and the conductive material, resulting in the planarizing rate of the planarization process to the conductive material being different from the planarizing rate of the planarization process to the conductive layer. Besides, since the conductive layer is pulled down, the conductive layer is not polished by the planarization process. Therefore, the galvanic corrosion between the barrier layer and the conductive layer can be avoided in the present invention.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor process, comprising:
forming a dielectric layer having a recess on a substrate;
forming a barrier layer covering the recess;
forming a conductive layer by an atomic layer deposition process on the barrier layer, thereby the conductive layer having two sidewall parts; and
pulling down the two sidewall parts of the conductive layer.

2. The semiconductor process according to claim 1, wherein the dielectric layer comprises an inter-level dielectric layer.

3. The semiconductor process according to claim 1, wherein the barrier layer comprises a titanium nitride layer.

4. The semiconductor process according to claim 1, wherein the two sidewall parts of the conductive layer are pulled down by performing a fluorine containing dry etching process to remove a portion of the two sidewall parts of the conductive layer.

5. The semiconductor process according to claim 1, wherein the conductive layer is formed and pulled down in-situ.

6. The semiconductor process according to claim 1, further comprising:
filling a conductive material in the recess and contacting exposed parts of the barrier layer caused by pulling down the two sidewall parts of the conductive layer.

7. The semiconductor process according to claim 6, wherein the conductive material is formed by a chemical vapor deposition (CVD) process.

8. The semiconductor process according to claim 6, wherein forming and pulling down the conductive layer, and filling the conductive material are in-situ.

9. The semiconductor process according to claim 6, wherein the equilibrium potential difference between the barrier layer and the conductive layer is different from the equilibrium potential difference between the barrier layer and the conductive material.

10. The semiconductor process according to claim 1, further comprising:
performing a planarization process on the conductive material and the barrier layer until the dielectric layer is exposed.

11. (canceled)

12. The semiconductor process according to claim 10, wherein the planarization process is a chemical mechanical polishing (CMP) process.

13. The semiconductor process according to claim 12, wherein the slurry of the planarization process comprises hydrogen peroxide (H2O2).

14. The semiconductor process according to claim 10, wherein the conductive layer is not polished by the planarization process.

15. A semiconductor structure, comprising:
a dielectric layer having a recess located on a substrate;
a barrier layer conformally covering the recess, thereby the barrier layer having two sidewall parts;
a conductive layer conformally covering the barrier layer, wherein the conductive layer has two sidewall parts, and the two sidewall parts of the barrier layer protrude from the two sidewall parts of the conductive layer; and
a conductive material filling the recess and having a part contacting the two sidewall parts of the barrier layer protruding from the two sidewall parts of the conductive layer, wherein the equilibrium potential difference between the barrier layer and the conductive layer is different from the equilibrium potential difference between the barrier layer and the conductive material.

16. The semiconductor structure according to claim 15, wherein the dielectric layer comprises an inter-level dielectric layer.

17. The semiconductor structure according to claim 15, wherein the barrier layer comprises a titanium nitride layer.

18. The semiconductor structure according to claim 15, wherein the conductive layer and the conductive material comprise tungsten.

19. The semiconductor structure according to claim 15, wherein the conductive material has a top surface level with top surfaces of the two sidewall parts of the barrier layer.
